(19) United States
(12) Patent Application Publication
(10) Pub. No.: US 2025/0248124 A1
(43) Pub. Date: Jul. 31, 2025

(54) DISPLAY PANEL AND TILING DISPLAY DEVICE INCLUDING THE SAME

(71) Applicant: LG Display Co., Ltd., Seoul (KR)

(72) Inventors: Chang Bae PARK, Paju-si (KR); Seok Ho SHIM, Paju-si (KR)

(73) Assignee: LG Display Co., Ltd., Seoul (KR)

(21) Appl. No.: 18/929,011

(22) Filed: Oct. 28, 2024

(30) Foreign Application Priority Data
Jan. 29, 2024 (KR) 10-2024-0012904

(51) Int. Cl. H01L 27/12; H01L 23/60; H01L 25/16

(52) U.S. Cl. CPC H10D 86/60; H01L 23/60; H01L 25/167; H10D 86/441

(57) ABSTRACT

A display panel and a tiling display device including the same are discussed. The display panel can include a first side part and a second side part facing each other, a third side part and a fourth side part facing each other, a pixel area in which one or more pixels are disposed, and a low-potential power supply layer configured to supply low-potential power to the one or more pixels. The first side part can include a side line, and the low-potential power supply layer can include an extension portion disposed on the third side part. According to the display panel, it is possible to increase the probability of electrostatic discharge (ESD) applied to a combination part or a rear surface of a display device being discharged through an ESD protection circuit.

### CROSS-REFERENCE TO RELATED APPLICATION

This application claims priority to Korean Patent Application No. 10-2024-0012904, filed in the Republic of Korea on Jan. 29, 2024, the entire contents of which is hereby expressly incorporated by reference into the present application.

### BACKGROUND

### 1. Field of the Invention

The present disclosure relates to a display panel and a tiling display device including the same.

### 2. Discussion of the Related Art

Organic light emitting display devices display images by emitting light from organic light emitting diodes (OLEDs) disposed in each pixel according to input image signals. Organic light emitting display devices have fast pixel response times, and high luminous efficiency and luminance, and wide viewing angles, and can express black gray scale as perfect black, and thus have an excellent contrast ratio and color gamut. The organic light emitting display devices do not require a backlight unit.

Recently, display devices that use light emitting diodes (LEDs) that are inorganic light emitting elements as light emitting elements of pixels are attracting attention as next generation display devices. LEDs are formed of inorganic materials, and thus do not require a separate encapsulation layer to protect organic materials from moisture and have better reliability and a longer lifetime than OLEDs. In addition, LEDs have fast lighting speeds and high luminous efficiency, and impact resistance.

When manufacturing or using the display devices, electrostatic discharge (hereinafter referred to as “ESD”) can be generated. Such ESD can cause problems such as insulation breakdown or short circuits between thin film layers of display panels. Therefore, there is a need to prevent an overcurrent and/or an overvoltage due to the ESD from flowing into the display panels.

### SUMMARY OF THE DISCLOSURE

The present disclosure is directed to solving the above-described and other needs and/or problems associated with the related art.

Objects of the present disclosure are not limited to those mentioned above, and other objects not mentioned will be clearly understood by those skilled in the art from the following description.

A display panel according to aspects of the present disclosure includes a first side part and a second side part facing each other, a third side part and a fourth side part facing each other, a pixel area in which one or more pixels are disposed, and a low-potential power supply layer configured to supply low-potential power to the one or more pixels, wherein the first side part includes a side line, and the low-potential power supply layer includes an extension portion disposed in the third side part.

The display panel according to one embodiment of the present disclosure can include a first substrate on which a light emitting element and a pixel circuit configured to drive the light emitting element are disposed on a front surface and a second substrate disposed on a rear surface of the first substrate, and the low-potential power supply layer can be disposed on a rear surface of the second substrate.

The display panel according to one embodiment of the present disclosure can include a first pad electrode disposed on the front surface of the first substrate and a second pad electrode disposed on the rear surface of the second substrate, and the side line can electrically connect the first pad electrode and the second pad electrode.

The display panel according to one embodiment of the present disclosure can include an ESD protection circuit, and the ESD protection circuit can be disposed in a driving driver including the pixel circuit configured to drive the one or more pixels.

In one embodiment of the present disclosure, the ESD protection circuit can be disposed on a front surface of the first substrate.

In one embodiment of the present disclosure, the low-potential power supply layer can include a first metal layer, a low-potential insulation layer disposed on the first metal layer, and a second metal layer disposed on the low-potential insulation layer, and can include the extension portion.

In one embodiment of the present disclosure, the low-potential insulation layer includes a contact hole that brings the first metal layer into contact with the second metal layer.

In one embodiment of the present disclosure, the first metal layer or the second metal layer can include a hole, and the second metal layer can be formed to include aluminum (Al).

In one embodiment of the present disclosure, the extension portion can include a plurality of protrusions protruding in a direction in which the third side part is disposed.

In one embodiment of the present disclosure, the extension portion can include a bridge portion configured to connect the plurality of protrusions.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a block diagram schematically showing a configuration of a display device according to an embodiment of the present disclosure.

FIG. 2 is a cross-sectional view schematically showing a part of the display device according to one embodiment of the present disclosure.

FIG. 3 is a perspective view showing a tiling display device according to one embodiment of the present disclosure.

FIG. 4 is a block diagram schematically showing control boards connected to a plurality of printed circuit boards and a system board connected to the control boards.

FIG. 5 is a plan view schematically showing a planar structure of a display panel according to one embodiment of the present disclosure.

FIG. 6 is a cross-sectional view specifically showing a cross-sectional structure of the display panel according to one embodiment of the present disclosure.

FIG. 7 is a cross-sectional view specifically showing a cross-sectional structure of a display panel according to another embodiment of the present disclosure.

FIG. 8 is a view schematically showing a structure of a third metal layer according to one embodiment of the present disclosure.

FIG. 9 is a view schematically showing a structure of a third metal layer according to another embodiment of the present disclosure.

FIG. 10 is a view schematically showing a structure of a third metal layer according to still another embodiment of the present disclosure.

FIG. 11 is a view schematically showing a structure of a driving driver according to one embodiment of the present disclosure.

FIG. 12 is a circuit diagram showing an electrostatic discharge (ESD) protection circuit according to one embodiment of the present disclosure.

FIG. 13 is a circuit diagram showing an ESD protection circuit according to another embodiment of the present disclosure.

### DETAILED DESCRIPTION OF THE EMBODIMENTS

Advantages and features of the present invention, and methods of achieving them, will become clear by referring to embodiments described in detail below along with the accompanying drawings. The scope of the invention according to the present disclosure is not limited to the embodiments disclosed below, but can be implemented in various different forms, and the embodiments are merely provided to make the disclosure of the invention according to the present disclosure complete. The present disclosure is provided to fully inform those skilled in the art to which the invention according to the present disclosure pertains of the scope of the invention according to the present disclosure, and the scope of the invention according to the present disclosure is only defined by the scope of the appended claims. Here, the terms “present invention” and “present disclosure” are interchangeably used. Further, the term “can” fully encompasses all the meanings and coverages of the term “may.”

In describing the invention according to the present disclosure, when it is determined that detailed description of related known art can unnecessarily obscure the gist of the present disclosure, the detailed description will be omitted.

When the terms “provides,” “can include,” “has,” “consists of,” and the like mentioned in the present disclosure are used, other parts can be added unless “only” is used. When a component is expressed in the singular, it can be interpreted as plural unless otherwise specifically stated.

When a positional relationship or interconnected relationship between two components such as “on,” “above,” “under,” “next to,” “connected or coupled to,” crossing, or intersecting is described, one or more other components can be interposed between the components unless the term “right” or “directly” is used.

When a temporal relationship such as “after,” “following,” “next,” or “before” is described, it may not be continuous on the time axis unless “immediately” or “directly” is used.

Further, “first,” “second,” etc. can be used to distinguish components, but the function or structure of the components is not limited by the ordinal number in front of the components or the component name.

The following embodiments can be partially or fully combined or mixed with each other, and various types of technological interworking and driving are possible. Each embodiment of the present disclosure can be implemented independently any others or they can be implemented together in an associated relationship.

Terms (including technical and scientific terms) used in the embodiments disclosed in the present disclosure can be interpreted with meanings that can be commonly understood by those skilled in the art to which the invention according to the present disclosure pertains, unless otherwise specifically defined and described, and the meanings of commonly used terms, such as dictionary-defined terms, can be interpreted by considering the contextual meaning in the related art.

In a tiling display device according to aspects of the present disclosure, a pixel circuit and a gate driving circuit can include a plurality of transistors. The transistors can be oxide TFTs including oxide semiconductors. Alternatively, the transistors can be a low temperature poly silicon (LTPS) TFTs including LTPS.

The transistor is a three-electrode element including a gate, a source, and a drain. The source is an electrode that supplies carriers to the transistor. In the transistor, the carriers begin to flow from the source. The drain is an electrode from which the carriers exit the transistor. In the transistor, the carriers flow from the source to the drain.

Hereinafter, embodiments of the present disclosure will be described in detail with reference to the accompanying drawings. All the components of the present disclosure are operatively coupled and configured.

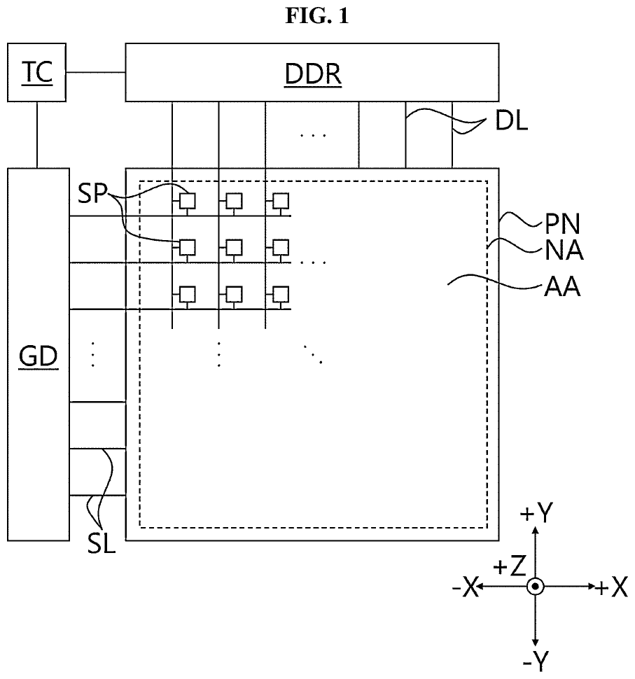

FIG. 1 is a block diagram schematically showing a configuration of a display device according to an embodiment of the present disclosure.

Referring to FIG. 1, the display device can include a display panel PN having a plurality of pixels disposed in a display area AA (or active area), and a driving circuit for driving the pixels.

The display panel PN can be a panel of a rectangular structure having a length in a first direction (e.g., a +X axis direction), a width in a second direction (e.g., a +Y axis direction) intersecting the first direction, and a thickness in a third direction (e.g., a +Z axis direction) intersecting both the first and second directions.

The length of the display panel PN can extend in a fourth direction (e.g., a −X direction) that forms a predetermined angle with the first direction. The width of the display panel PN can extend in a fifth direction (e.g., a −Y direction) that forms a predetermined angle with the second direction. The thickness of the display panel PN can extend in a sixth direction (e.g., a −Z direction) that forms a predetermined angle with the third direction.

In the display panel PN, the third direction from the plane defined by the first and second directions can be a front surface direction of the display panel PN. In the display panel PN, the sixth direction from the plane defined by the fourth and fifth directions can be a rear surface direction of the display panel PN.

The pixels can include a plurality of sub-pixels SP of different colors. The driving circuit can include a data driving unit DDR, a gate driving unit GD, and a timing controller TC for controlling the gate driving unit GD and the data driving unit DDR. The display area AA on which input images are displayed on the display panel PN can be a screen visible from a front surface of the display panel PN.

The input images can be displayed in the sub-pixels SP disposed in the display area AA of the display panel PN. Each of the sub-pixels SP can include a light emitting element and a pixel circuit for driving the light emitting element. The light emitting element can be a light-emitting diode (LED), a mini light-emitting diode, or a micro light-emitting diode.

On the display panel PN, a plurality of scan lines SL and a plurality of data lines DL can be disposed to intersect each other. Each of the sub-pixels SP can be connected to the scan lines SL and the data lines DL. Power lines can be connected to each of the sub-pixels SP. In the display panel PN, a non-display area NA (or non-active area) can be disposed outside the display area AA. The non-display area NA can surround the active area AA entirely or only in part(s).

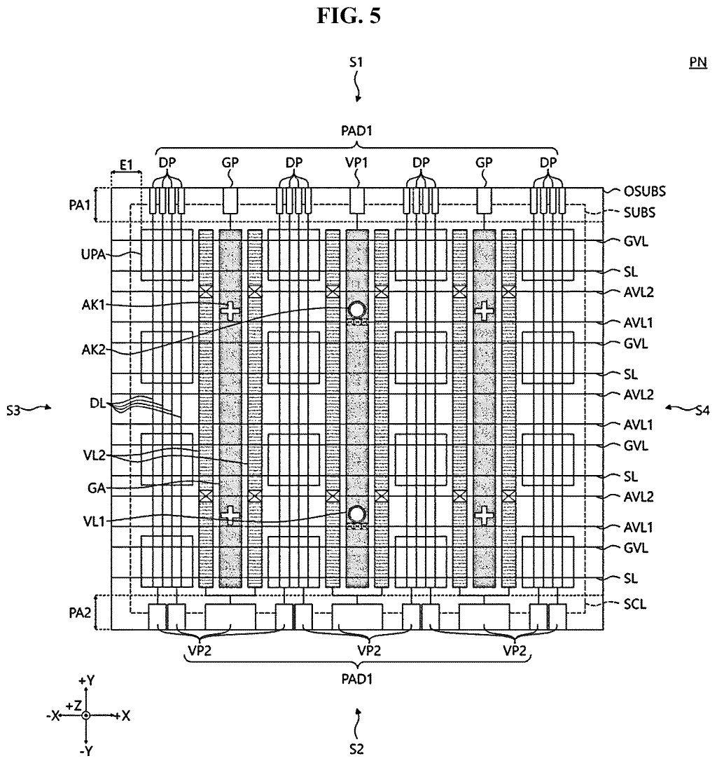

The gate driving unit GD can supply scan signals to the scan lines SL in response to gate control signals provided from the timing controller TC. The gate driving unit GD can be disposed in at least the non-display area NA of the display panel PN, or can be disposed in the display area AA as shown in the drawings (e.g., FIG. 5) described below.

The data driving unit DDR can convert image data received from the timing controller TC into a reference compensation voltage in response to a data control signal provided from the timing controller TC and output a data voltage. The data voltage output from the data driving unit DDR can be supplied to the data lines DL.

The timing controller TC can align the image data input from the outside and supply the image data to the data driving unit DDR. The timing controller TC can generate the gate control signals and the data control signals based on timing signals synchronized with input image signals, such as dot clock signals, data enable signals, and horizontal/vertical synchronization signals. The timing controller TC can control operation timings of the gate driving unit GD and the data driving unit DDR by supplying the gate control signals to the gate driving unit GD and supplying the data control signals to the data driving unit DDR.

In the non-display area NA, link lines and pad electrodes for transmitting signals to the sub-pixels SP of the display area AA can be disposed. In addition, one or more of a gate driver IC in which a circuit of the gate driving unit GD is integrated and a data driver IC in which a circuit of the data driving unit DDR is integrated can be disposed in the non-display area NA. The non-display area NA can be located on the rear surface of the display panel PN, such as the rear surface without the sub-pixels SP, or can be minimized to be invisible when images are displayed on the display panel PN.

Driving units such as the gate driving unit GD, the data driving unit DDR, and the timing controller TC can be connected to the display panel PN in various ways. For example, the gate driving unit GD can be disposed in a gate in panel (GIP) manner in the non-display area NA and disposed in a gate in active area (GIA) manner between the sub-pixels SP in the display area AA. For example, the data driving unit DDR and the timing controller TC can be formed on a separate flexible film and printed circuit board (PCB), and the flexible film and the PCB can be bonded to pad electrodes formed in the non-display area NA of the display panel PN to electrically connect the data driving unit DDR and the timing controller TC to the display panel PN.

A side line for connecting a signal line formed on the front surface of the display panel PN to the pad electrode formed on the rear surface of the display panel PN can be formed on an outermost side surface of the display panel PN. The non-display area NA visible on the front surface of the display panel PN can be minimized by electrically connecting the front and rear surfaces of the display panel PN via the side line.

A drawing reference numeral SRL indicates the side line. When the gate driving unit GD, the data driving unit DDR, and the timing controller TC are connected to the display panel PN in the above manner, a screen without a bezel can be substantially implemented.

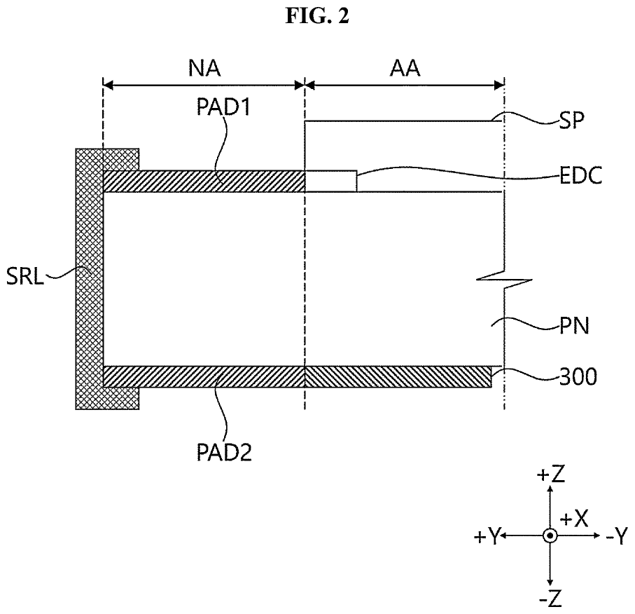

FIG. 2 is a cross-sectional view schematically showing a part of the display device according to one embodiment of the present disclosure.

Referring to FIG. 2, a plurality of pad electrodes for transmitting various signals to the sub-pixels SP can be disposed in the non-display area NA of the display panel PN. For example, a first pad electrode PAD1 that transmits signals to the sub-pixels SP can be disposed in the non-display area NA disposed on the front surface of the display panel PN. A second pad electrode PAD2 electrically connected to circuit components such as a flexible film and a PCB can be disposed in the non-display area NA disposed on the rear surface of the display panel PN. The non-display area NA disposed at the outermost front surface of the display panel PN on which images are displayed can be disposed in only a pad area in which the first pad electrode PAD1 is disposed, and thus minimized in size.

Various signal lines connected to the sub-pixels SP, such as scan lines or data lines, can extend to the non-display area NA and can be electrically connected to the first pad electrode PAD1. A low-potential power supply layer 300 can be disposed on the rear surface of the display panel PN.

The display panel PN can include a side line SRL disposed on the outermost side surface of the display panel PN. The side line SRL can electrically connect the first pad electrode PAD1 disposed at the outermost front surface of the display panel PN and the second pad electrode PAD2 disposed at the outermost rear surface of the display panel PN by crossing the side surface of the display panel PN. Signals output from circuit components disposed on the rear surface of the display panel PN can be transmitted to the sub-pixel SP in the display area AA through the second pad electrode PAD2, the side line SRL, and the first pad electrode PAD1. Therefore, an area of the non-display area NA on the front surface of the display panel PN can be minimized by forming a signal transmission path that crosses the front surface, the side surface, and the rear surface at the outermost edge of the display panel PN.

The display panel PN according to embodiments of the present disclosure can include a side part on which the side line SRL is disposed and a side part on which the side line SRL is not disposed. In a combined tiling display device, the side part that can be in direct contact with and/or combined with other display modules may not include the side line SRL so that a seam is not visible by adjusting a physical distance, or the like.

The display area AA of the display panel PN can include one or more driving drivers in which a plurality of pixel circuits are integrated. The non-display area NA can include one or more dummy driving drivers in which a plurality of pixel circuits are integrated.

The driving driver and the dummy driving driver can have substantially the same structure. Each of the driving driver and the dummy driving driver can include an ESD protection circuit EDC connected to input/output terminals of the pixel circuit. As shown, the ESD protection circuit EDC is disposed only in the display area AA, but is not limited thereto.

When ESD occurs, charges can flow to input/output terminals of the driving driver and dummy driving driver, and can be discharged to a ground line through the ESD protection circuit. Therefore, the pixel circuit can be protected from the ESD.

The ESD can be applied to the side part on which the side line is not disposed or to a rear surface of the tiling display device. The ESD needs to be discharged through the ESD protection circuit via the side line disposed on the side part including the side line.

In the tiling display device according to the present disclosure, since the side part of the display panel, which does not include the side line, includes the low-potential power supply layer including an extension portion, a surface area to which the ESD can be applied can be increased. As described above, it is possible to increase the probability that the ESD applied to the side part not including the side line to prevent the visible seam between the display panels due to the combination is discharged through the ESD protection circuit. In addition, it is possible to increase durability of the display device and increase lifetime.

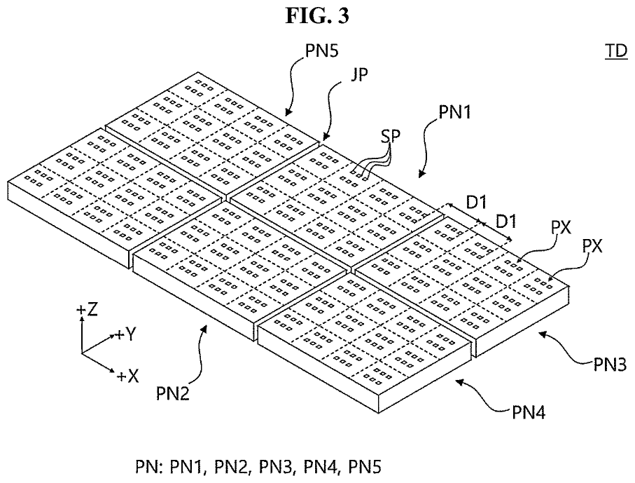

FIG. 3 is a perspective view showing a tiling display device according to one embodiment of the present disclosure.

Referring to FIG. 3, a plurality of display modules can be combined in a plane to be implemented as a large screen tiling display device. Each of the display modules can include one display panel PN, a driving circuit of the display panel PN, circuit components coupled to the rear surface of the display panel PN, and module cover members.

A large screen tiling display device TD can include a plurality of display modules disposed on the XY plane. Each of the display modules can include the display panel PN that displays input images. When the non-display area NA is minimized at the outermost front surface of each display panel PN, large screen images having invisible seams between neighboring display panels PN can be displayed.

The display panels PN can be assembled in a plane such that a distance D1 between an outermost pixel PX of one display panel PN and an outermost pixel PX of another display panel PN adjacent to the display panel PN is substantially the same as a distance D1 between neighboring pixels PX in the display area of the display panel PN. As a result, since the distance D1 between the adjacent pixels PX can be the same throughout the large screen display area of the tiling display device TD, the seam area can be invisible.

In the tiling display device TD, the plurality of display modules can share one timing controller TC. A host system connected to the plurality of timing controllers TC can transmit image signals to be displayed on all display panels PN implementing the large screen of the tiling display device TD to the timing controllers TC and synchronize the timing controllers TC.

Each display panel PN can include side parts. The side parts can include first and second side parts facing each other and third and fourth side parts facing each other in one display panel PN.

Since the plurality of display modules can be combined in the tiling display device TD, a combination part JP for contact between the plurality of display panels PN can be included. As described above, side members may not be disposed in the area including the combination part JP so that the seams between the display panels may not be visible when neighboring display panels PN1 and PN5 are disposed. For example, the side line SRL described below may not be disposed in a side part of a first display panel PN1 and a side part of a fifth display panel PN5, which are located in a direction in which the combination part JP where the first display panel PN1 and the fifth display panel PN5 are combined with each other is disposed. On the other hand, the side part of the first display panel PN1, that does not include the combination part JP (e.g., a side part disposed in the +Y-axis direction) can include the side members. For example, the side members can include the side line. The side line can electrically connect pad electrodes of a substrate disposed on the front surface of the display panel to pad electrodes of a substrate disposed on the rear surface of the display panel.

When the side members are disposed, ESD that is directly applied to an outer side part (e.g., the side part of the first display panel PN1 disposed in the +Y-axis direction) of the tiling display device TD can be discharged through the side line. On the other hand, the side part of the first display panel PN1 located in a direction in which the combination part JP is disposed can be vulnerable to the ESD because it does not include the side members. Therefore, the ESD applied to the side part of the first display panel PN1 located in the direction in which the combination part JP is disposed needs to be discharged through the ESD protection circuit via the side line disposed on the outer side part located in the +Y-axis direction.

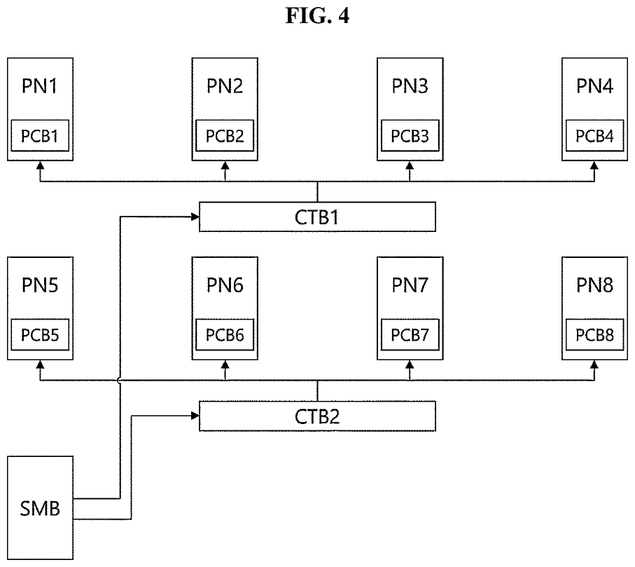

FIG. 4 is a block diagram schematically showing control boards connected to a plurality of printed circuit boards and a system board connected to the control boards.

Referring to FIG. 4, each of the display modules can include one display panel PN and one PCB. A system board SMB can be connected to M control boards CTB1 and CTB2 (M is an integer greater than or equal to 2). Each of the control boards CTB1 and CTB2 can be connected to N PCBs (N is an integer greater than M).

A first control board CTB1 can be connected to PCBs PCB1 to PCB4 of first to fourth display modules via a flexible film or a cable. A second control board CTB2 can be connected to PCBs PCB5 to PCB8 of fifth to eighth display modules via a flexible film or a cable. The system board SMB can be connected to the first and second control boards CTB1 and CTB2 via a flexible film or a cable.

The system board SMB can be a main board of the host system. The system board SMB can include a user interface port for receiving a user input, an external interface port connected to an external device, a communication module for delaying various communication protocols, a processor for processing multimedia signals, a central processing unit (CPU), a main power supply unit, etc. The system board SMB can transmit input image signals and timing signals to the control boards CTB1 and CTB2. The timing controllers mounted on the control boards CTB1 and CTB2 can transmit the received image signals to the data driving unit and control the data driving unit and the gate driving unit based on the timing signals. The driving circuits (e.g., the data driving unit or the gate driving unit) of the N display modules can write image data to the corresponding display panel PN under the control of one timing controller.

FIG. 5 is a plan view schematically showing a planar structure of the display panel according to one embodiment of the present disclosure.

Referring to FIG. 5, the display panel PN can include a substrate SUBS on which a pixel array and a circuit of the gate driving unit are disposed. The display panel PN can include a side area including the side line and a side area E1 that does not include the side line. The side area including the side line can correspond to a first pad area PA1.

The substrate SUBS can be an insulation substrate that supports components disposed on the upper portion of the display device. The substrate SUBS can have a structure in which a plurality of substrates are stacked. For example, the substrate SUBS can have a structure in which first and second substrates are stacked. Each of the first and second substrates can be formed of glass, a polymer resin, or a plastic substrate. Each of the first and second substrates can be formed of a flexible substrate having flexibility, but is not limited thereto.

On one surface (or a front surface) of the substrate SUBS, the display area can include a plurality of pixel areas UPA, a plurality of gate driving areas GA, and a plurality of pad areas PA1 and PA2. One or more pixels can be disposed in each of the pixel areas UPA. The pixel areas UPA can be disposed in a first direction (e.g., an X-axis direction) and a second direction (e.g., a Y-axis direction) intersecting the first direction. For example, the pixel areas UPA can be disposed in a plurality of row lines and a plurality of column lines.

Each of the pixels can include a plurality of sub-pixels SP of different colors. Each of the sub-pixels SP can include a light emitting element and a pixel circuit and emit light independently. The sub-pixels SP can include a red sub-pixel, a blue sub-pixel, and a green sub-pixel, etc. but are not limited thereto. For example, the sub-pixels SP can further include a white sub-pixel.

The plurality of gate driving areas GA can include a circuit of the gate driving unit GD. The gate driving area GA can be formed in the row and/or column directions between the plurality of pixel areas UPA. The gate driving unit formed in the gate driving area GA can provide scan signals to a plurality of scan lines SL.

The first pad area PA1 can include a plurality of first pad electrodes PAD1 disposed on the outermost front surface of one side (or an upper side) of the display panel PN. The first pad electrodes PAD1 can transmit various signals to various lines extending in the column direction in the display area. The first pad electrodes PAD1 can include data pads DP connected to the data lines DL to transmit data voltages from the data driving unit to the data lines DL, and gate pads GP connected to the gate driving unit GD to transmit clock signals, start signals, gate low voltages, gate high voltages, etc. for driving the gate driving unit GD to the gate driving unit. The clock signals, the start signals, the gate low voltages, the gate high voltages, etc. for driving the gate driving unit GD can be generated from the timing controller TC and applied to the gate pads GP via a level shifter and a PCB.

The first pad electrodes PAD1 can include a plurality of power lines to which a direct current voltage (or a constant voltage) is applied.

The second pad area PA2 can include a plurality of first pad electrodes PAD1 disposed on the outermost front surface of the other side (or a lower side) of the display panel PN. The second pad area PA2 can include a plurality of low-potential power pads VP2.

A direct current voltage applied to power lines can be output from a power circuit and applied to the pads VP1 and VP2 connected to the power lines through the PCB. The power circuit can be a DC-DC converter that is disposed on a PCB or control boards CTB1 and CTB2 disposed on the rear surface of the display panel PN and converts a DC input voltage from the main power unit into a DC voltage suitable for driving the display panel PN.

The power pads VP1 and VP2 connected to the power lines can include a plurality of high-potential power pads VP1 disposed on the first pad area PA1 to transmit a high-potential power voltage to the high-potential power lines VL1, and a plurality of low-potential power pads VP2 disposed on the second pad area PA2 to transmit a low-potential power voltage to the low-potential power lines VL2.

The data pads DP connected one-to-one to the data lines DL can have a relatively narrow width, and the power pads VP1 and VP2 and the gate pads GP can have a relatively wide width. The low-potential power pads VP2 can have a wider width than the high-potential power pads VP2. The widths of the pads DP, GP, VP1, and VP2 are not limited by the drawings.

In order to minimize the outermost non-display area NA of the display panel PN, after the pixel array, lines, and pads are formed on a front surface of a substrate OSUBS of the display panel PN, an outermost edge of the substrate OSUBS can be cut and removed along the dotted scribing line SCL to provide a substrate SUBS. After the scribing process, the outermost rough edges of the substrate OSUBS can be ground or laser trimmed. In this way, short pad electrodes PAD1 and PAD2 can be left on the outermost front surface of the substrate SUBS reduced in size.

The data lines DL can extend in a second direction (e.g., a Y-axis direction or column direction) on a first substrate SUBS and overlap the pixel area UPA. The data lines DL can supply data voltages to the pixel circuit of each of the sub-pixels SP.

The scan lines SL can extend in a first direction (e.g., an X-axis direction or row direction) on the substrate SUBS of the display panel PN and overlap the pixel area UPA and the gate driving area GA. The scan lines SL can cross the pixel area UPA and the gate driving area GA and supply scan signals from the gate driving unit to the pixel circuit of each of the sub-pixels SP.

The high-potential power lines VL1 can extend in the second direction, and at least one thereof can be connected in a mesh structure to an auxiliary high-potential power line AVL1 extending in the first direction. The auxiliary high-potential power line AVL1 can be connected to the sub-pixels SP disposed in the first direction. Therefore, the high-potential power voltage applied to the high-potential power lines VL1 can be transmitted to the sub pixels SP through the auxiliary high-potential power lines AVL1.

The low-potential power lines VL2 can extend in the second direction, and at least one thereof can be connected in a mesh structure to an auxiliary low-potential power line AVL2 extending in the first direction. The auxiliary low-potential power line AVL2 can be connected to the sub-pixels SP disposed in the first direction. Therefore, the sub-pixels SP can be connected to the auxiliary low-potential power line AVL2 to which the low-potential power voltage is applied.

Since a resistance of the power line is reduced due to the mesh structures of the power lines, a voltage drop of the high-potential power voltage and a deviation in the power voltage in the display area can be improved.

The substrate SUBS of the display panel PN can have one or more alignment keys AK1 and AK2 disposed between the pixel areas UPA. The alignment keys AK1 and AK2 can be used for alignment in the manufacturing process of the display panel PN.

A first alignment key AK1 can be disposed in the gate driving area GA. The first alignment key AK1 can be used to check the alignment location of each of the light emitting elements. The first alignment key AK1 can be formed in a cross pattern, but is not limited thereto.

A second alignment key AK2 can overlap the high-potential power line VL1. Since the high-potential power line VL1 can include a hole formed at a location overlapping the second alignment key AK2, the second alignment key AK2 and the high-potential power line VL1 can be distinguished. The second alignment key AK2 can be used to align the display panel PN and a donor substrate. The donor substrate is an intermediate medium for mounting the light emitting element on the substrate SUBS of the display panel PN. The plurality of light emitting elements manufactured on a semiconductor wafer can be attached to the donor substrate and transported, and the light emitting elements attached to the donor substrate can be transferred onto the substrate SUBS. The second alignment key AK2 can be formed in a circular or ring pattern, but is not limited thereto.

As described above, the display panel PN can include side parts S1, S2, S3, and S4. The side parts S1, S2, S3, and S4 can include a first side part S1 and a second side part S2 facing each other, and a third side part S3 and a fourth side part S4 facing each other.

The fourth side part S4 can be a display panel PN disposed in a first direction (e.g., a +X axis direction), the first side part S1 can be a display panel PN disposed in a second direction (e.g., a +Y axis direction) intersecting the first direction, the third side part S3 can be a display panel PN disposed in a third direction (e.g., a −X axis direction) opposite the first direction, and the second side part S2 can be a display panel PN disposed in a fourth direction (e.g., a −Y axis direction) opposite to the second direction.

The first pad electrode PAD1 can be disposed on the first side part S1. The second pad electrode PAD2 can be disposed on the second side part S2.

For example, the shown display panel PN can be the first display panel PN1 shown in FIG. 3. The first side part S1 can include the side line, and the second to fourth side parts S2, S3, and S4 may not include the side line. However, the present invention is not limited thereto, and the first to fourth side parts S1, S2, S3, and S4 and whether or not the side line is included can be independent of each other.

For example, the first side part S1 and the fourth side part S4 of the third display panel PN3 shown in FIG. 3 can include the side line, but the second side part S2 and the third side part S3 may not include the side line.

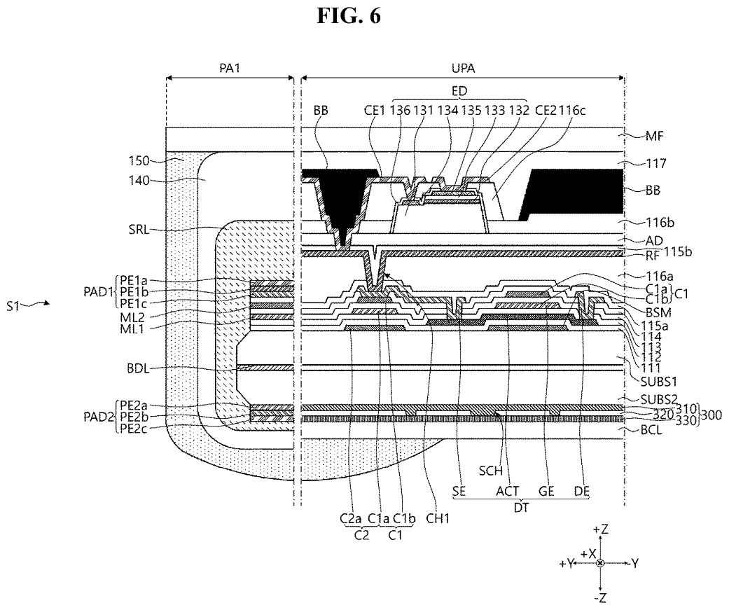

FIG. 6 is a cross-sectional view showing in detail a cross-sectional structure of the display panel according to one embodiment of the present disclosure.

Referring to FIG. 6, a pixel circuit for driving a light emitting element ED can be disposed in each of a plurality of sub-pixels SP on a first substrate SUBS1. The pixel circuit can include a plurality of thin film transistors and one or more capacitors. In the drawing, for convenience of description, a driving transistor DT, a first capacitor C1, and a second capacitor C2 are shown in the pixel circuit, but other circuit elements can be further included.

A pattern of a first metal layer can be disposed on the first substrate SUBS1. The pattern of the first metal layer can include a light blocking layer BSM. The light blocking layer BSM can minimize a leakage current by blocking light incident on an active layer ACT of the driving transistor DT. The light blocking layer BSM is formed of an opaque conductive material, for example, a metal such as copper (Cu), aluminum (Al), molybdenum (Mo), nickel (Ni), titanium (Ti), or chromium (Cr), an alloy of these metals, or multilayered metal layers.

A buffer layer 111 can be disposed on the light blocking layer BSM. The buffer layer 111 can block permeation of moisture or impurities through the first substrate SUBS1. The first metal layer can be formed of silicon oxide (SiOx), silicon nitride (SiNx), or multilayered insulation layers.

The driving transistor DT including the active layer ACT, a gate electrode GE, a source electrode SE, and a drain electrode DE can be disposed on the buffer layer 111.

The active layer ACT can be formed of a semiconductor material such as an oxide semiconductor, amorphous silicon, or polysilicon, but is not limited thereto. A gate insulation layer 112 can electrically insulate the active layer ACT and the gate electrode GE of the driving transistor DT. The gate insulation layer 112 can be formed of silicon oxide (SiOx), silicon nitride (SiNx), or multilayered insulation layers.

A pattern of a second metal layer can be disposed on the gate insulation layer 112. The pattern of the second metal layer can include the gate electrode GE of the driving transistor DT. The second metal layer can be formed of copper (Cu), aluminum (Al), molybdenum (Mo), nickel (Ni), titanium (Ti), chromium (Cr), or multilayered metal layers.

A first interlayer insulation layer 113 and a second interlayer insulation layer 114 can be disposed on the gate electrode GE. In the first interlayer insulation layer 113 and the second interlayer insulation layer 114, contact holes can be formed so that each of the source electrode SE and the drain electrode DE of the driving transistor DT can be connected to the active layer ACT. Each of the first interlayer insulation layer 113 and the second interlayer insulation layer 114 can be formed of silicon oxide (SiOx), silicon nitride (SiNx), or multilayered insulation layers.

A pattern of a third metal layer can be disposed on the second interlayer insulation layer 114. The pattern of the third metal layer can overlap the active layer ACT and include the source electrode SE and the drain electrode DE connected to the active layer ACT via the contact holes passing through the interlayer insulation layers 113 and 114. The source electrode SE can be connected to the capacitors C1 and C2 and a first electrode 134 of the light emitting element ED. The third metal layer can be formed of copper (Cu), aluminum (Al), molybdenum (Mo), nickel (Ni), titanium (Ti), chromium (Cr), or multilayered metal layers.

The first capacitor C1 can include a first capacitor electrode C1a and a second capacitor electrode C1b. The first capacitor electrode C1a can be formed of the pattern of the second metal layer disposed on the gate insulation layer 112. The second capacitor electrode C1b can be formed of a pattern of a fourth metal layer disposed on the first interlayer insulation layer 113 and overlap the first capacitor electrode C1a with the first interlayer insulation layer 113 interposed therebetween. The second capacitor electrode C1b can be connected to the source electrode SE of the driving transistor DT. The fourth metal layer can be formed of copper (Cu), aluminum (Al), molybdenum (Mo), nickel (Ni), titanium (Ti), chromium (Cr), or multilayered metal layers.

The second capacitor C2 can include a third capacitor electrode C2a overlapping the first capacitor electrode C1a with the insulation layers 111 and 112 interposed therebetween. The third capacitor electrode C2a can be formed of the pattern of the first metal layer disposed on the first substrate SUBS1.

The second capacitor C2 can be electrically connected between the source electrode SE of the driving transistor DT and the light emitting element ED to increase the capacitance of the light emitting element ED, thereby increasing the brightness when the light emitting element ED is emitted.

A first passivation layer 115a covers the pattern of the third metal layer and the second interlayer insulation layer 114 to cover the pattern of the third metal layer. The first passivation layer 115a can be formed of silicon oxide (SiOx), silicon nitride (SiNx), or multilayered insulation layers.

A first planarization layer 116a can be disposed on the first passivation layer 115a. The first planarization layer 116a can be formed of silicon oxide (SiOx), silicon nitride (SiNx), or multilayered insulation layers. The first planarization layer 116a can planarize a surface on which the light emitting element is disposed by covering the first passivation layer 115a. The first planarization layer 116a can be a thick single layer or multilayered organic insulation layers formed of benzocyclobutene or acrylic-based organic materials.

A pattern of a fifth metal layer can be disposed on the first planarization layer 116a. The pattern of the fifth metal layer can include a reflective layer RF. The reflective layer RF can increase light efficiency by reflecting light from the light emitting element ED toward the front surface of the display panel PN and can be used as an electrode to connect the light emitting element ED to the pixel circuit or the power line. The reflective layer RF can be electrically connected to the source electrode SE of the driving transistor DT and the first capacitor C1 via a contact hole CH1 passing through the first planarization layer 116a and the first passivation layer 115a. In addition, the reflective layer RF can be electrically connected to the first electrode 134 of the light emitting element ED via a first connection electrode CE1, or electrically connected to a second electrode 135 of the light emitting element ED and the high-potential power line VL1 described above. The fifth metal layer can be formed of a transparent electrode material such as silver (Ag), aluminum (Al), molybdenum (Mo), titanium (Ti), or indium tin oxide (ITO), or multilayered metal layers.

A second passivation layer 115b covers the pattern of the fifth metal layer and the first planarization layer 116a. The second passivation layer 115b can be formed of silicon oxide (SiOx), silicon nitride (SiNx), or multilayered insulation layers.

An adhesive layer AD can be disposed on the second passivation layer 115b to fix the light emitting element ED. The adhesive layer AD can be formed of a photocurable resin that can be cured by light. The adhesive layer AD can be formed of an acrylic-based material including a photosensitizer, but is not limited thereto. The adhesive layer AD can be formed on the entire surface of the first substrate SUBS1 excluding pad areas PA1 and PA2 in which the first pad electrode PAD1 is disposed.

The light emitting element ED of each of the sub-pixels SP can be disposed on the adhesive layer AD. The light emitting elements ED can be emitted by a current from the driving transistor DT. The light emitting elements ED can include a red light emitting element ED, a green light emitting element ED, and a blue light emitting element ED. The light emitting element ED can be a light emitting diode (LED) or micro LED.

Each of the light emitting elements ED can include a first semiconductor pattern 131, a light emitting layer 132, a second semiconductor pattern 133, the first electrode 134, and the second electrode 135.

The first semiconductor pattern 131 can be disposed on the adhesive layer AD, and the second semiconductor pattern 133 can be disposed on the first semiconductor pattern 131. The first semiconductor pattern 131 and the second semiconductor pattern 133 can be formed of semiconductor patterns obtained by doping n-type and p-type impurities into a semiconductor material. For example, each of the first semiconductor pattern 131 and the second semiconductor pattern 133 can be a layer doped with n-type or p-type impurities in a material such as gallium nitride (GaN), indium aluminum phosphide (InAlP), gallium arsenide (GaAs), etc. In addition, the p-type impurity can be magnesium, zinc (Zn), beryllium (Be), etc., and the n-type impurity can be silicon (Si), germanium, tin (Sn), etc., but neither is limited thereto.

The light emitting layer 132 can be disposed between the first semiconductor pattern 131 and the second semiconductor pattern 133. The light emitting layer 132 can emit light by receiving holes and electrons from the first semiconductor pattern 131 and the second semiconductor pattern 133. The light emitting layer 132 can be formed as a single layer or multi-quantum well (MQW) structure and formed of, for example, indium gallium nitride (InGaN), gallium nitride (GaN), etc.

The first electrode 134 can be disposed on the first semiconductor pattern 131. The first electrode 134 can electrically connect the driving transistor DT and the first semiconductor pattern 131. The first semiconductor pattern 131 can be formed of a semiconductor layer doped with n-type impurities. The first electrode 134 can be an anode electrode of the light emitting element ED disposed on the first semiconductor pattern 131 and electrically connected to the driving transistor DT and the capacitors C1 and C2 via the reflective layer RF. The first electrode 134 can be disposed on an upper surface of the first semiconductor pattern 131. The first electrode 134 can be formed of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof.

The second electrode 135 can be disposed on the second semiconductor pattern 133. The second electrode 135 can electrically connect the high-potential power line VL1 and the second semiconductor pattern 133. The second semiconductor pattern 133 can be formed of a semiconductor layer doped with p-type impurities. The second electrode 135 can be a cathode electrode of the light emitting element ED. The second electrode 135 can be formed of a conductive material, for example, a transparent conductive material such as indium tin oxide (ITO) or indium zinc oxide (IZO), or an opaque conductive material such as titanium (Ti), gold (Au), silver (Ag), copper (Cu), or an alloy thereof.

The light emitting element ED can include a sealing layer 136. The sealing layer 136 can protect the light emitting element ED by covering the semiconductor patterns 131 and 133 and the electrodes 134 and 135. The sealing layer 136 and the third planarization layer 116c can include contact holes exposing the first electrode 134 and the second electrode 135. The first connection electrode CE1 can be connected to the reflective layer RE via a first contact hole passing through the sealing layer 136 and the third planarization layer 116c. A second connection electrode CE2 can be connected to the second electrode 135 via a second contact hole passing through the sealing layer 136 and the third planarization layer 116c. Meanwhile, a portion of the side surface of the first semiconductor pattern 131 can be exposed without the sealing layer 136.

The second planarization layer 116b and the third planarization layer 116c can cover the adhesive layer AD and the light emitting element ED. The second planarization layer 116b can be in contact with a lower end of a side surface of the light emitting element ED to fix the light emitting element ED. The third planarization layer 116c can cover the light emitting element ED on the second planarization layer 116b. The third planarization layer 116c can include contact holes exposing the first electrode 134 and the second electrode 135 of the light emitting element ED. The second planarization layer 116b and the third planarization layer 116c can be formed of a single layer or a multilayered organic insulation material such as a photoresist or an acryl-based organic material.

A pattern of a sixth metal layer can be disposed on the third planarization layer 116c. The sixth metal layer can include the first connection electrode CE1 and the second connection electrode CE2. The first connection electrode CE1 can electrically connect the first electrode 134 of the light emitting element ED and the reflective layer RF. The first connection electrode CE1 can be connected to the first electrode 134 of the light emitting element ED via contact holes passing through the insulation layers 116c and 136, and connected to the reflective layer RF via contact holes passing through the insulation layers 115b, AD, 116b, and 116c.

The second connection electrode CE2 can be connected to the second electrode 135 of the light emitting element ED via contact holes passing through the insulation layers 116c and 136. The second connection electrode CE2 can be connected to the low-potential power line VL2 described above.

A bank pattern BB can be disposed on the second planarization layer 116b. The bank pattern BB can be spaced apart from the light emitting element ED with regular intervals. The bank pattern BB can cover a portion of the first connection electrode CE1 present in the contact holes passing through the insulation layers 116b and 116c. The bank pattern BB can reduce color mixing between the sub-pixels SP by preventing optical crosstalk between the sub-pixels SP. To this end, the bank pattern BB can be formed of a black resin, but is not limited thereto.

A first protective layer 117 can cover the patterns of the sixth metal layer CE1 and CE2, the bank pattern BB, the second planarization layer 116b, and third planarization layer 116c. The first protective layer 117 can be formed of a single layer or multilayered insulation layers of translucent epoxy, silicon oxide (SiOx), or silicon nitride (SiNx).

Each of the first pad electrodes PAD1 disposed in the pad areas PA1 and PA2 of the first substrate SUBS1 can have a structure of a multilayered metal layer. For example, each of the first pad electrodes PAD1 can include a first pad metal layer PE1a, a second pad metal layer PE1b, and a third pad metal layer PE1c stacked on the outermost front surface of the first substrate SUBS1.

The pattern of the third metal layer disposed on the second interlayer insulation layer 114 can further include the first pad metal layer PE1a. The first pad metal layer PE1a can be formed of the same metal as the source electrode SE and drain electrode DE of the driving transistor DT, such as copper (Cu), aluminum (Al), molybdenum (Mo), nickel (Ni), titanium (Ti), chromium (Cr), or multilayered metal layers.

The pattern of the fifth metal layer disposed on the first planarization layer 116a can further include the second pad metal layer PE1b. The second pad metal layer PE1b can be formed of the same metal as the reflective layer RF, such as silver (Ag), aluminum (Al), molybdenum (Mo), or multilayered metal layers.

The pattern of the sixth metal layer disposed on the third planarization layer 116c can further include the third pad metal layer PE1c. The third pad metal layer PE1c is formed of the same conductive material as the first connection electrode CE1 and the second connection electrode CE2, such as a transparent conductive material such as indium tin oxide (ITO) or indium zinc oxide (IZO), or multilayered metal layers.

A first metal layer ML1, a second metal layer ML2, and a plurality of insulation layers can be disposed under the first pad electrodes PAD1. A step of the first pad electrode PAD1 can be adjusted by disposing the first metal layer ML1, the second metal layer ML2, and the plurality of insulation layers under the first pad electrode PAD1. For example, the buffer layer 111, the gate insulation layer 112, the first metal layer ML1, the first interlayer insulation layer 113, and the second metal layer ML2 can be sequentially disposed between the first pad electrode PAD1 and the first substrate SUBS1. The pattern of the second metal layer disposed on the gate insulation layer 112 can include the first metal layer ML1. The pattern of the fourth metal layer disposed on the first interlayer insulation layer 113 can include the second metal layer ML2. The plurality of insulation layers and the metal layers ML1 and ML2 under the first pad electrodes PAD1 are not limited thereto.

A second substrate SUBS2 can be disposed on the rear surface of the first substrate SUBS1. A bonding layer BDL can be disposed between the first substrate SUBS1 and the second substrate SUBS2. The bonding layer BDL can be cured via various curing methods to bond the first substrate SUBS1 and the second substrate SUBS2. The bonding layer BDL can be disposed only in a partial area between the first substrate SUBS1 and the second substrate SUBS2, or can be disposed in the entire area. The first substrate SUBS1 and the second substrate SUBS2 are scribed and ground at the same time so that the first substrate SUBS1 and the second substrate SUBS2 can have the side surfaces having no steps.

A plurality of second pad electrodes PAD2 can be disposed on the outermost rear surface of the second substrate SUBS2. The second pad electrodes PAD2 can be electrically connected to the side lines SRL and the first pad electrodes PAD1 to transmit signals from circuit components disposed on the rear surface of the second substrate SUBS2 to the sub-pixels SP disposed on the upper surface of the first substrate SUBS1.

Each of the second pad electrodes PAD2 can have a structure of a multilayered metal layer. For example, each of the second pad electrodes PAD2 can include a first pad metal layer PE2a, a second pad metal layer PE2b, and a third pad metal layer PE2c stacked on the outermost rear surface of the second substrate SUBS2. Each of the first and second pad metal layers PE2a and PE2b can be formed of copper (Cu), aluminum (Al), molybdenum (Mo), nickel (Ni), titanium (Ti), chromium (Cr), or multilayered metal layers. The third pad metal layer PE2c can be formed of a transparent conductive material such as indium tin oxide (ITO) or indium zinc oxide (IZO).

A second protective layer BCL can be disposed on the rear surface of the second substrate SUBS2. The second protective layer BCL can cover various lines excluding the second pad electrodes PAD2 on the rear surface of the second substrate SUBS2. The second protective layer BCL can be formed of an organic insulation material and formed of, for example, benzocyclobutene or acrylic-based organic insulation materials.

Circuit components such as a plurality of flexible films and a PCB can be disposed on the rear surface side of the second substrate SUBS2. Output terminals of the flexible film can be electrically connected to the second pad electrode PAD2 and input terminals of the flexible film can be electrically connected to output terminals of the PCB. Therefore, a signal or voltage output from the PCB can be transmitted to the sub-pixel SP disposed on the front surface of the first substrate SUBS1 via the flexible film, the second pad electrode PAD2, the side line SRL, the plurality of first pad electrodes PAD1, and lines connected to the first pad electrode PAD1.

A low-potential power supply layer 300 for supplying the low-potential power can be disposed on the rear surface of the second substrate SUBS2. The low-potential power supply layer 300 can be connected to the low-potential power line VL2 described above and consequently connected to the second electrode 135 via the second connection electrode CE2. The low-potential power supply layer 300 disposed on the rear surface of the display panel can receive a direct current voltage applied from the power circuit and apply the low-potential power to the low-potential power pad VP2 connected to the power lines including the low-potential power line VL2 described above. In one embodiment of the present disclosure, the low-potential power supply layer 300 can be connected to the second pad electrode PAD2 to apply the low-potential power to the low-potential power pad VP2 of the first pad electrode PAD1 through the side line SRL.

In one embodiment of the present disclosure, the second electrode 135 is a cathode electrode and the low-potential power supply layer 300 can supply a cathode voltage to the light emitting element ED.

The low-potential power supply layer 300 can include a third metal layer 310, a fourth metal layer 330, and a low-potential insulation layer 320 disposed between the third metal layer 310 and the fourth metal layer 330.

The third metal layer 310 can be disposed on the lower surface (e.g., in the rear surface direction of the display panel or in the −Z-axis direction) of the second substrate SUBS2. The third metal layer 310 can be formed of copper (Cu), aluminum (Al), molybdenum (Mo), nickel (Ni), titanium (Ti), chromium (Cr), or multilayered metal layers. In a preferred embodiment, the third metal layer 310 can be formed of aluminum (AL).

The low-potential insulation layer 320 can be disposed under the third metal layer 310. The low-potential insulation layer 320 can prevent a short circuit due to contact of the multilayered metal layers 310 and 330. A low-potential contact hole SCH for bringing the third metal layer 310 into contact with the fourth metal layer 330 can be formed in the low-potential insulation layer 320. In order to bring the third metal layer 310 into contact with the fourth metal layer 330, the number of low-potential contact holes SCH can be adjusted according to the needs of the operator. For example, a plurality of low-potential contact hole SCH can be provided. The low-potential insulation layer 320 can be formed of silicon oxide (SiOx), silicon nitride (SiNx), or multilayered insulation layers.

The fourth metal layer 330 can be disposed under the low-potential insulation layer 320. The fourth metal layer 330 can be formed of copper (Cu), aluminum (Al), molybdenum (Mo), nickel (Ni), titanium (Ti), chromium (Cr), or multilayered metal layers. In a preferred embodiment, the fourth metal layer 330 can be formed of aluminum (Al).

The side lines SRL can electrically connect the first pad electrodes PAD1 and the second pad electrodes PAD2 by crossing side surfaces of the first substrate SUBS1 and the second substrate SUBS2. The side lines SRL can be formed on the side surfaces of the substrates SUBS1 and SUBS2 by a pad printing method using conductive inks including, for example, silver (Ag), copper (Cu), molybdenum (Mo), chromium (Cr), etc.

A side insulation layer 140 can cover the side lines SRL formed on the outermost upper, side, and rear surfaces of the bonded substrates SUBS1 and SUBS2. When the side lines SRL are made of metal, external light can be reflected from the side line SRL, or light emitted from the light emitting element ED can be reflected from the side line SRL and can be visible to the user. The side insulation layer 140 can include a black material absorbing external light to minimize the degradation of image quality due to such reflected light. For example, the side insulation layer 140 can be formed on the outermost edges of the substrates SUBS1 and SUBS2 using a black ink capable of being applied by a printing method.

A seal 150 can cover the side insulation layer 140 to protect the display panel PN from external impact, moisture, oxygen, etc. For example, the seal 150 can be formed of polyimide (PI), polyurethane, epoxy, or acrylic-based insulating materials.

A functional film MF can cover the front surface of the first display panel PN. The functional film MF can be one or more of various functional films, such as an anti-shattering film, an anti-glare film, an anti-reflecting film, a low-reflecting film, an OLED transmittance controllable film, a color difference compensation film, a polarizer, etc. The anti-shattering film can prevent substrate pieces or particles from scattering when the display panel PN is broken. The functional film MF can be removed by cutting with the outer part of the seal 150 along a cutting line that overlaps the seal 150 after the seal 150 is widely adhered to the front surface of the first substrate SUBS1. As a result, the exposed side surfaces at the outermost end of the functional film MF and the seal 150 can form side surfaces of the same plane without a step.

When the shown display panel is the first display panel PN1 shown in FIG. 3, the display panel of the first side part S1 is shown in FIG. 6. Alternatively, FIG. 6 shows a cross-sectional view of a side part without a combination part.

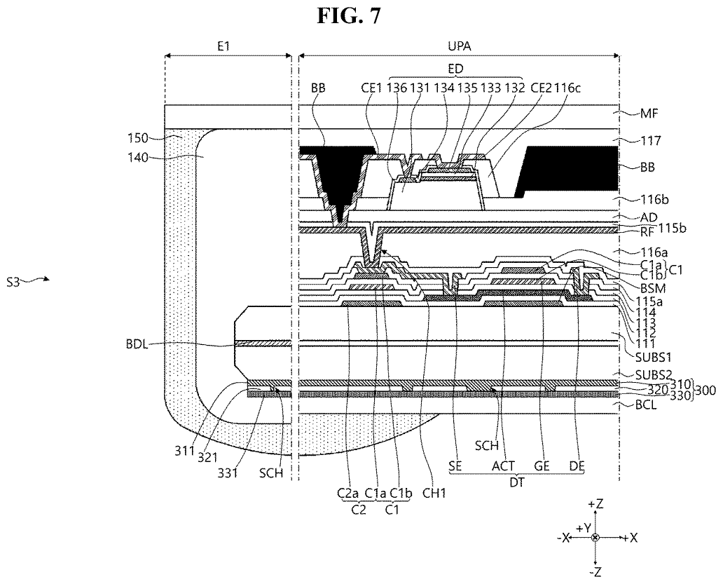

FIG. 7 is a cross-sectional view specifically showing a cross-sectional structure of a display panel according to another embodiment of the present disclosure. Components having substantially the same functions as those in the embodiments described above are denoted by the same reference numerals, and repeated descriptions thereof will be omitted or may be briefly provided.

Referring to FIG. 7, the shown display panel can be the first display panel shown in FIG. 3. The third side part S3 is coupled to the fifth display panel in the −X axis direction, and thus may not include a side line.

In a combined tiling display device, the side part that can be in direct contact with and/or combined with another display module may not include the side members so that a seam is not visible by adjusting a physical distance. The side line may not be disposed in an area including the combination part so that the seam between the display panels is not visible.

The low-potential power supply layer 300 can extend to both the pixel area UPA and the pad area PA1 and can be disposed under the second substrate SUBS2. The third metal layer 310 can include an extension portion 311 of the third metal layer extending to a side area E1 that does not include the side line. The low-potential insulation layer 320 can include an extension portion 321 of the low-potential insulation layer extending to the side area E1 that does not include the side line. The fourth metal layer 330 can include an extension portion 331 of the fourth metal layer extending to the side area E1 that does not include the side line.

At least one of the plurality of extension portions 311, 321 and 331 can be formed to overlap the second substrate SUBS2 in the side area E1 that does not include the side line in the plane direction of the display panel. At least one of the plurality of extension portions 311, 321 and 331 can be formed to extend to both the lower part and the side surfaces of the second substrate SUBS2 to surround the second substrate. Therefore, since ESD applied to both the lower part of the display panel and the combination part can be discharged to protect the display panel, it is possible to increase the lifetime of the display device.

In one embodiment of the present disclosure, the entire low-potential power supply layer 300 can extend to the pad area PA1 311, 321 and 331, and only the third metal layer 310 can extend, or the third metal layer 310 and the low-potential insulation layer 320 can extend. Preferably, only the third metal layer 310 can extend.

The side insulation layer 140 can cover the low-potential power supply layer 300 formed on the outermost upper, side, and rear surfaces of the substrates SUBS1 and SUBS2 bonded together. The side insulation layer 140 can include a black material that absorbs external light. For example, the side insulation layer 140 can be formed on the outermost edges of the substrates SUBS1 and SUBS2 using a black ink capable of being applied by a printing method.

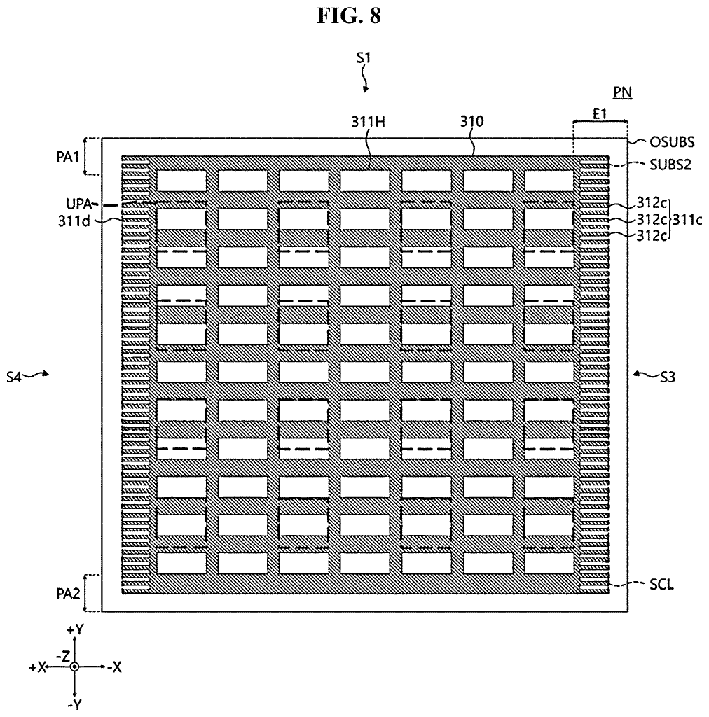

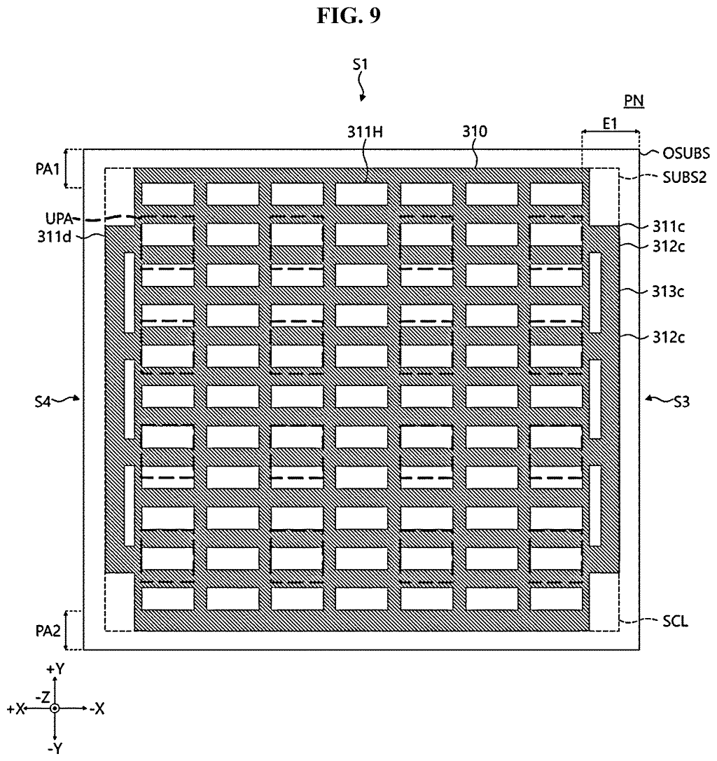

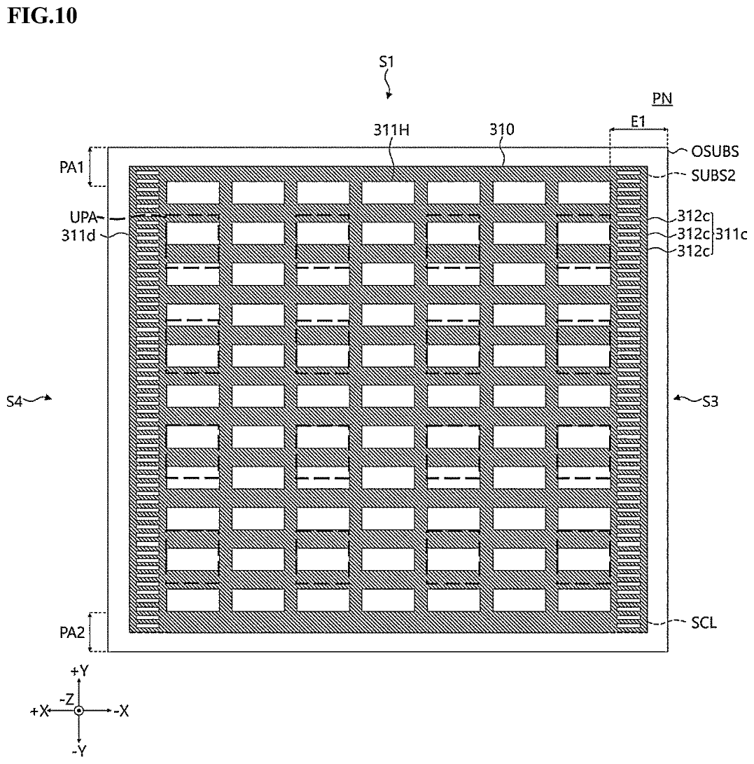

FIG. 8 is a view schematically showing a structure of a third metal layer according to one embodiment of the present disclosure. FIG. 9 is a view schematically showing a structure of a third metal layer according to another embodiment of the present disclosure. FIG. 10 is a view schematically showing a structure of a third metal layer according to still another embodiment of the present disclosure. Components having substantially the same functions as those of the embodiments described above are denoted by the same reference numerals and repeated descriptions thereof will be omitted or may be briefly provided.

Referring to FIGS. 8 to 10, a display panel PN can include a second substrate SUBS2. A low-potential power supply layer can be disposed in a direction (e.g., a −Z-axis direction) of the rear surface of the second substrate SUBS2. The low-potential power supply layer can include a third metal layer 310, a low-potential insulation layer, and a fourth metal layer 330. In the shown drawing, only the third metal layer 310 is shown, but the present invention is not limited thereto. The following description can be equally applied to the low-potential power supply layer or the fourth metal layer 330.

The third metal layer 310 can be formed of a single electrode on the rear surface of the second substrate SUBS2. Since the low-potential power supply layer can be formed of a plurality of metal layers, the third metal layer 310 can include a plurality of holes 311H to prevent a short circuit between the metal layers. The shapes of the holes 311H can be quadrangular or circular shapes, but are not limited thereto. The holes 311H can overlap the pixel area UPA in the plane direction.

For example, the shown display panel PN can be the first display panel PN1 shown in FIG. 3. In this case, the first side part S1 can be a side part that includes the side line, and the third side part S3 part can be a side part that does not include the side line. Hereinafter, the description will be made assuming that the shown display panel is the first display panel PN1 shown in FIG. 3, but the present invention is not limited thereto.

The third metal layer 310 can include an extension portion 311c disposed on the third side part S3. The third metal layer 310 can include an extension portion 311d disposed on the fourth side part S4. The extension portion 311c can be the third metal layer 310 disposed in the side area E1 that does not include the side line.

The extension portion 311c can include needle-shaped protrusions 312c with a relatively thin thickness. Since the perimeter length of the third metal layer 310 can be increased when more protrusions 312c are formed, a surface area of the third metal layer 310 disposed on the third side part S3 in three dimensions can be increased. Accordingly, since an area to which ESD is applied is increased, it is possible to increase discharge probability, thereby efficiently protecting the display panel.

In one embodiment of the present disclosure, the extension portion 311c can include a bridge portion 313c connecting the plurality of protrusions 312c. By including the bridge portion 313c, it is possible to reduce the manufacturing cost in the manufacturing process of the display panel while maintaining the increased surface area of the third metal layer 310.

According to the tiling display device according to the present disclosure, the side part of the display panel not including the side line can include the low-potential power supply layer including the extension portion. Accordingly, it is possible to increase the surface area to which the ESD can be applied. The extension portion can serve as a lightning rod. Therefore, it is possible to increase the probability that the ESD applied to the combination part or the rear surface of the display device can be discharged through the ESD protection circuit. Accordingly, it is possible to increase the durability and lifetime of the display device.

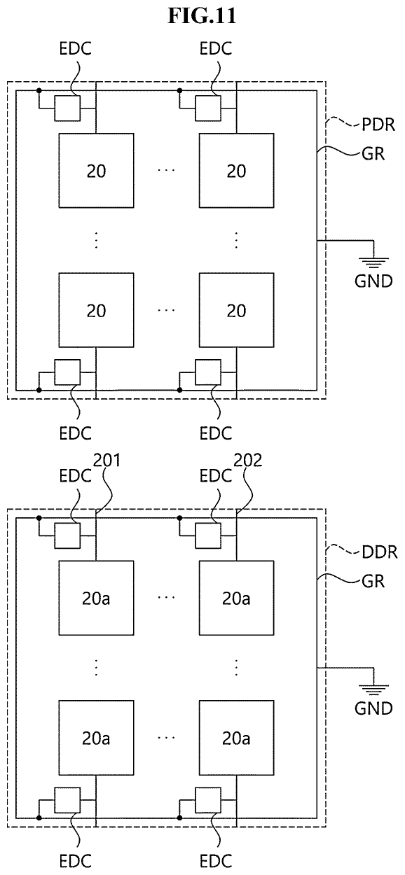

FIG. 11 is a view schematically showing a structure of a driving driver according to one embodiment of the present disclosure.

Referring to FIG. 11, the display area can include one or more driving drivers PDR in which a plurality of pixel circuits 20 are integrated. The non-display area can include one or more dummy driving drivers DDR in which a plurality of pixel circuits 20a are integrated.

The driving driver PDR and the dummy driving driver DDR can have substantially the same structure. Each of the driving driver PDR and the dummy driving driver DDR can include an ESD protection circuit EDC connected to input/output terminals of the pixel circuits 20 and 20a. When ESD occurs, charges can flow to the input/output terminals of the driving driver PDR and the dummy driving driver DDR and can be discharged to a ground line GR which is grounded via a GND through the ESD protection circuit EDC. Accordingly, the pixel circuits 20 and 20a can be protected from ESD.

A first terminal 201 and a second terminal 202 of the dummy driving driver DDR can each be connected to the side line SRL described above.

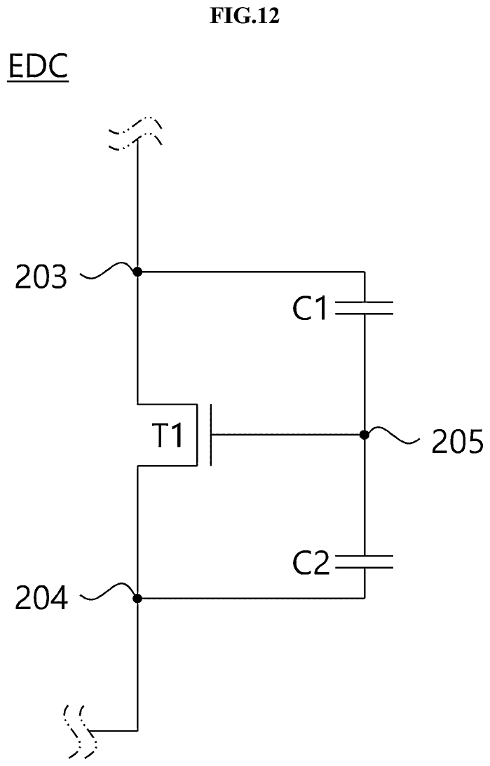

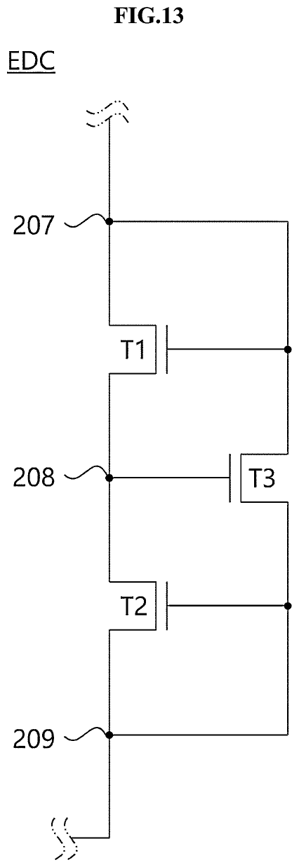

The ESD protection circuit EDC can be implemented in various structures. The ESD protection circuit EDC can be implemented as a circuit as shown in FIGS. 12 and 13, but is not limited thereto.

FIG. 12 is a circuit diagram showing an ESD protection circuit according to one embodiment of the present disclosure. FIG. 13 is a circuit diagram showing an ESD protection circuit according to another embodiment of the present disclosure.

Referring to FIG. 12, the ESD protection circuit can include a transistor T1 connected between a first node 203 and a second node 204, a first capacitor C1 connected between the first node 203 and a third node 205, and a second capacitor C2 connected between the second node 203 and the third node 205. The input/output terminals of the dummy driving driver DDR can be connected to the first node 203 and the second node 204 can be connected to the ground line GR described above.

The transistor T1 can include a drain electrode connected to the first node 203, a source electrode connected to the second node 204, and a gate electrode connected to the third node 205.

When ESD occurs and charges flow into the inside of the dummy driving driver DDR through the input/output terminals of the dummy driving driver DDR, the voltage of the first node 203 can be increased and the gate voltage of the transistor T1 through the first capacitor C1 can be increased so that the transistor T1 can be turned on. Therefore, a large amount of charges generated by ESD can be discharged through the ground line GR described above.

Referring to FIG. 13, the ESD protection circuit can include a transistor T1 connected between a first node 207 and a second node 208, a second transistor T2 connected between the second node 208 and a third node 209, and a third transistor T3 connected between the first node 207 and the third node 209. The input/output terminals of the dummy driving driver DDR can be connected to the first node 207 and the third node 209 can be connected to the ground line GR described above.

The first transistor T1 can include a drain electrode and a gate electrode connected to the first node 207 and a source electrode connected to the second node 208. The second transistor T2 can include a drain electrode connected to the second node 208, and a source electrode and a gate electrode connected to the third node 209. The third transistor T3 can include a drain electrode connected to the first node 207, a gate electrode connected to the second node 208, and a source electrode connected to the third node 209.

When ESD occurs and charges flow into the inside of the dummy driving driver DDR through the input/output terminals of the dummy driving driver DDR, the voltage of the first node 207 can be increased so that the transistors T1, T2, and T3 can be turned on. Therefore, a large amount of charges generated by ESD can be discharged through the ground line GR.

According to aspects of the present disclosure, a surface area to which the ESD can be applied can be increased.

According to aspects of the present disclosure, the probability of the ESD applied to a combination part or a rear surface of a display device being discharged through an ESD protection circuit can be increased.

According to aspects of the present disclosure, the durability and lifetime of the display device can be increased.

Although embodiments of the present invention have been described in detail with reference to the accompanying drawings, the present invention is not necessarily limited to these embodiments and can be modified in various ways without departing from the technical spirit.

Therefore, the embodiments disclosed in the present invention are not intended to limit the technical spirit of the present invention but are for illustrative purposes, and the scope of the technical spirit of the present invention is not limited by these embodiments.

Therefore, the embodiments described above should be understood in all respects as exemplary and not restrictive.

The scope of protection of the present invention should be interpreted in accordance with the claims, and all technical spirit within the equivalent scope thereof should be interpreted as being included in the scope of rights of the present invention.

What is claimed is:

1. A display panel comprising:
a first side part and a second side part facing each other;
a third side part and a fourth side part facing each other;
a pixel area in which one or more pixels are disposed; and
a low-potential power supply layer configured to supply low-potential power to the one or more pixels,
wherein the first side part includes a side line, and
wherein the low-potential power supply layer includes an extension portion disposed on the third side part.

2. The display panel of claim 1, further comprising:
a first substrate on which a light emitting element and a pixel circuit configured to drive the light emitting element are disposed on a front surface thereof; and
a second substrate disposed on a rear surface of the first substrate,
wherein the low-potential power supply layer is disposed on a rear surface of the second substrate.

3. The display panel of claim 2, further comprising:
a first pad electrode disposed on the front surface of the first substrate; and
a second pad electrode disposed on the rear surface of the second substrate,
wherein the side line electrically connects the first pad electrode and the second pad electrode.

4. The display panel of claim 3, further comprising an electrostatic discharge (ESD) protection circuit,
wherein the ESD protection circuit is disposed in a driving driver including the pixel circuit configured to drive the one or more pixels.

5. The display panel of claim 4, wherein the ESD protection circuit is disposed on the front surface of the first substrate.

6. The display panel of claim 1, wherein the low-potential power supply layer includes:
a first metal layer;
a low-potential insulation layer disposed on the first metal layer; and
a second metal layer disposed on the low-potential insulation layer and including the extension portion.

7. The display panel of claim 6, wherein the low-potential insulation layer includes a contact hole that brings the first metal layer into contact with the second metal layer.

8. The display panel of claim 7, wherein the first metal layer or the second metal layer includes a hole, and
wherein the second metal layer includes aluminum (Al).

9. The display panel of claim 1, wherein the extension portion includes a plurality of protrusions protruding in a direction in which the third side part is disposed.

10. The display panel of claim 9, wherein the extension portion includes a bridge portion configured to connect the plurality of protrusions.

11. A tiling display device comprising:
a first display panel including a first side part and a second side part facing each other, a third side part and a fourth side part facing each other, a pixel area in which one or more pixels are disposed, and a low-potential power supply layer configured to supply low-potential power to the one or more pixels; and
a second display panel disposed to be combined with the first display panel,
wherein the low-potential power supply layer includes an extension portion disposed on the third side part.

12. The tiling display device of claim 11, wherein the second display panel is disposed to be combined with the first display panel in a direction in which the third side part is disposed, and
wherein the first side part includes a side line.

13. The tiling display device of claim 11, wherein the first display panel includes:
a first substrate on which a light emitting element and a pixel circuit configured to drive the light emitting element are disposed on a front surface thereof; and
a second substrate disposed on a rear surface of the first substrate, and
wherein the low-potential power supply layer is disposed on a rear surface of the second substrate.

14. The tiling display device of claim 13, further comprising:
a first pad electrode disposed on the front surface of the first substrate; and
a second pad electrode disposed on the rear surface of the second substrate,
wherein the second display panel is disposed to be combined with the first display panel in a direction in which the third side part is disposed, and
wherein the first side part includes a side line electrically connecting the first pad electrode and the second pad electrode.

15. The tiling display device of claim 14, further comprising an electrostatic discharge (ESD) protection circuit,
wherein the ESD protection circuit is disposed in a driving driver including the pixel circuit configured to drive the one or more pixels.

16. The tiling display device of claim 15, wherein the ESD protection circuit is disposed on the front surface of the first substrate.

17. The tiling display device of claim 11, wherein the low-potential power supply layer includes:
a first metal layer;
a low-potential insulation layer disposed on the first metal layer; and
a second metal layer disposed on the low-potential insulation layer and including the extension portion.

18. The tiling display device of claim 17, wherein the low-potential insulation layer includes a contact hole that brings the first metal layer into contact with the second metal layer.

19. The tiling display device of claim 18, wherein the first metal layer or the second metal layer includes a hole, and
wherein the second metal layer includes aluminum (AI).

20. The tiling display device of claim 11, wherein the extension portion includes a plurality of protrusions protruding in a direction in which the third side part is disposed.
